(19) United States
(12) Patent Application Publication
(10) Pub. No.: US 2023/0138555 A1
(43) Pub. Date: May 4, 2023

(54) PLASMA PROCESSING CHAMBER WITH MULTILAYER PROTECTIVE SURFACE

(71) Applicant: Lam Research Corporation, Fremont, CA (US)

(72) Inventors: Amir A. YASSERI, San Jose, CA (US); Duane OUTKA, Fremont, CA (US)

(21) Appl. No.: 17/911,949

(22) PCT Filed: Mar. 17, 2021
(86) PCT No.: PCT/US2021/022814

§ 371 Date: Sep. 15, 2022

Related U.S. Application Data
(60) Provisional application No. 62/992,259, filed on Mar. 20, 2020.

(51) Int. Cl. H01J 37/32

(52) U.S. Cl. CPC H01J 37/32495; H01J 2237/3321; H01J 2237/3343

(57) ABSTRACT

Plasma processing chamber is provided where the plasma processing chamber has a first component. A first plurality of multilayers is disposed over the first component, wherein each multilayer comprises a process layer and a conditioning layer adjacent to the process layer, wherein the process layer is more etch resistant to a processing plasma than the conditioning layer and wherein the conditioning layer is configured to be selectively etched with respect to the process layer; and wherein the process layer is configured to be selectively etched with respect to the conditioning layer.

### CROSS-REFERENCE TO RELATED APPLICATION

This application claims the benefit of priority of U.S. Application No. 62/992,259, filed Mar. 20, 2020, which is incorporated herein by reference for all purposes.

### BACKGROUND

The disclosure relates to a plasma processing chamber for forming semiconductor devices on a semiconductor wafer.

In the formation of semiconductor devices, plasma processing chambers are used to process the semiconductor devices. The plasma processes may deposit on or erode surfaces of the plasma processing chamber.

Ceramic coatings, such as yttria coatings may be used to protect components of the plasma processing chambers. However, such coatings are still damaged by plasma processing.

The background description provided here is for the purpose of generally presenting the context of the disclosure. Information described in this background section, as well as aspects of the description that may not otherwise qualify as prior art at the time of filing, are neither expressly nor impliedly admitted as prior art against the present disclosure.

### SUMMARY

To achieve the foregoing and in accordance with the purpose of the present disclosure, a plasma processing chamber is provided where the plasma processing chamber has a first component. A first plurality of multilayers is disposed over the first component, wherein each multilayer comprises a process layer and a conditioning layer adjacent to the process layer, wherein the process layer is more etch resistant to a processing plasma than the conditioning layer and wherein the conditioning layer is configured to be selectively etched with respect to the process layer; and wherein the process layer is configured to be selectively etched with respect to the conditioning layer.

In another manifestation, a component for use in a plasma processing chamber is provided with a component body. A first plurality of multilayers is disposed over the component body, wherein each multilayer comprises a process layer and a conditioning layer adjacent to the process layer, wherein the process layer is more etch resistant to a processing plasma than the conditioning layer and wherein the conditioning layer is configured to be selectively etched with respect to the process layer; and wherein the process layer is configured to be selectively etched with respect to the conditioning layer.

In another manifestation, a method of using a first component is provided, where the first component has a first plurality of multilayers disposed over the first component, wherein each multilayer comprises a process layer made of an etch-resistant material, wherein the etch-resistant material does not form a contaminant during plasma processing and a conditioning layer disposed adjacent to the process layer, wherein the conditioning layer is configured to be selectively etched with respect to the process layer and wherein the process layer is configured to be selectively etched with respect to the conditioning layer. The component is used in a plasma processing chamber to process a plurality of wafers in the plasma processing chamber. An exposed process layer is selectively removed with respect to the conditioning layer. An exposed conditioning layer is selectively removed with respect to a process layer.

These and other features of the present disclosure will be described in more detail below in the detailed description of the disclosure and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a flow chart of an embodiment.

FIGS. 2A-E are schematic cross-sectional views of a section of a component of a plasma processing chamber processed according to an embodiment.

FIG. 3 is a schematic view of a plasma processing chamber that may employ an embodiment.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

During the processing of semiconductor devices, a plasma processing chamber may be used for plasma deposition, plasma etching, or for other processes used in manufacturing semiconductor devices. Such plasma processing may deposit on and/or etch surfaces of the plasma processing chamber. Components of the plasma processing chambers have surfaces used to maintain the plasma environment. Such components may be aluminum to provide electrical and thermal characteristics that are useful in maintaining the plasma. Aluminum also allows a reduction in weight and cost. A coating on the surface of the aluminum is needed to protect the aluminum surface. To minimize defects, depositions on the plasma processing chamber surfaces must be removed and surfaces that are etched may need to be replaced or reconditioned.

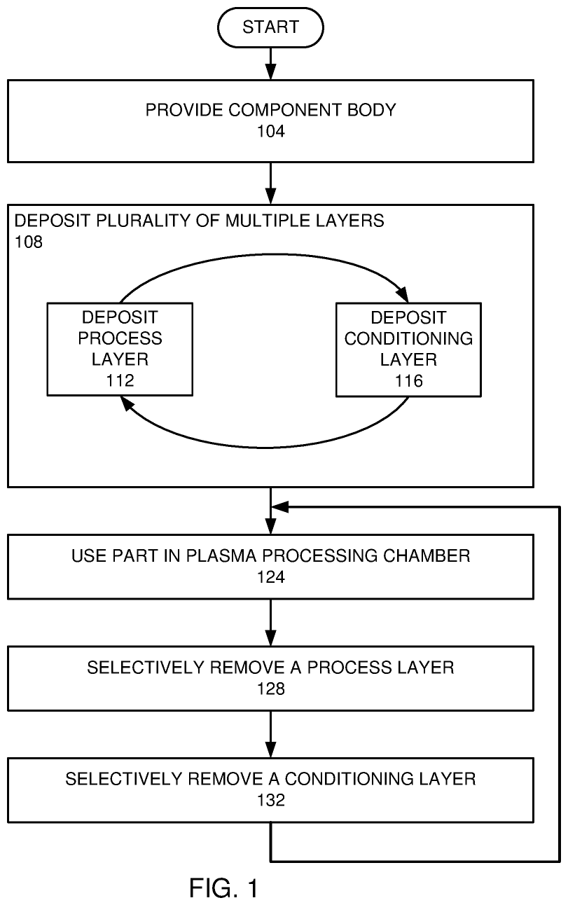

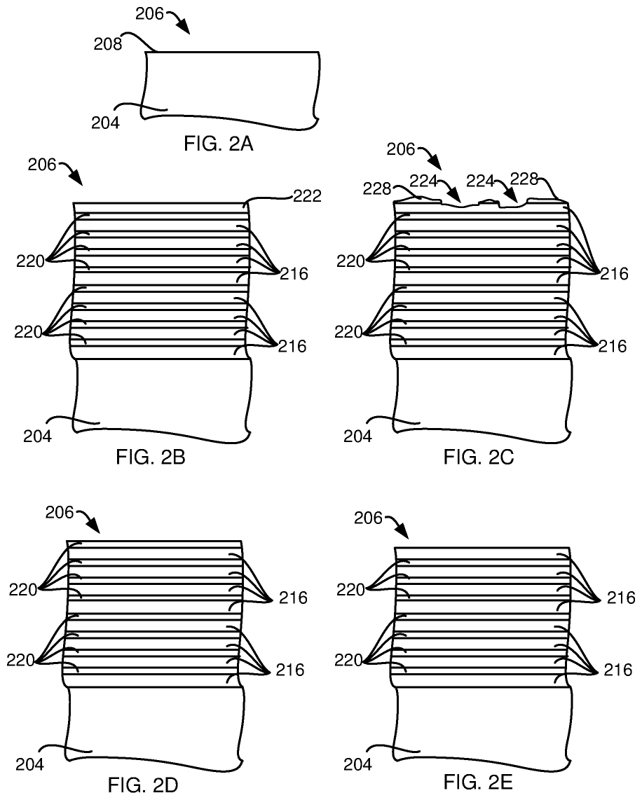

FIG. 1 is a flow chart of an embodiment. A component body is provided (step 104). In an example, FIG. 2A is a cross-sectional schematic view of a section of a component body 204 of a component 206. In this example, the component body 204 is made of aluminum (Al). In other embodiments, the component body 204 is made of some form of an aluminum oxide or a ceramic, such as alumina. The component body 204 has a surface 208 that is uncoated. The component body 204 may form gas injectors, showerheads, gas weldment assemblies, transformer coupled plasma windows, electrodes, or chamber liners.

A plurality of multilayers is deposited using a cyclical process (step 108). The cyclical process includes a plurality of cycles, where each cycle comprises depositing a multilayer. The multilayer can have multiple layers. In this embodiment, each multilayer includes a process layer and a conditioning layer, and each cycle comprises sequentially depositing the process layer (step 112) and depositing the conditioning layer on the process layer (step 116). In this embodiment, each of the plurality of multilayers is a bilayer with a process layer of yttrium oxide (Y₂O₃) and a conditioning layer of SiO₂. In other embodiments, the conditioning layer may be zirconium dioxide (ZrO₂). In this embodiment, eight bilayers, each including the process layer and the conditioning layer, are deposited. The process layer and the conditioning layer are deposited using a chemical vapor deposition (CVD) process. In other embodiments, the process layer and the conditioning layer are deposited using at least one of a chemical vapor deposition (CVD) process, an atomic layer deposition (ALD) process, an aerosol deposition (AD) process, a plasma-enhanced physical vapor deposition (PEPVD) process, a thermal spray process, or a physical vapor deposition (PVD) process.

FIG. 2B is a cross-sectional view of the component body 204 of the component 206 on which eight bilayers have been deposited. The bilayers have been deposited on the surface 208 of the component body 204. Each bilayer comprises a process layer 216 of Y₂O₃ and a conditioning layer 220 of SiO₂. In other words, sixteen (16) alternating or interleaving process layers 216 and conditing layers 220 are formed. An additional process layer 222 is deposited over the bilayers, so that a process layer 216 is exposed during the processing of a wafer. The process layers 216 and conditioning layers 220 are not drawn to scale in order to better illustrate the different layers. In this example, the process layers 216 are shown as thicker than the conditioning layers 220. In other embodiments, the process layers 216 may be thinner than the conditioning layers 220.

In other embodiments, the process layers 216 and/or the conditioning layers 220 may be deposited or formed with one or more interlayer materials sandwiched in between such that a multilayer may be made up of more than just two material layers.

In other embodiments, the process layers 216 and/or the conditioning layers 220 may be uniquely patterned onto a localized surface region of the component body 204 during the depositing or forming of the process layer 216 and/or the conditioning layers 220. The localized patterning provides more protection in specific areas that need more protection and less or no protection in specific areas that need less protection. The localized patterning can yield superior tunability within the chamber processing environment condition (i.e., more robust plasma erosion from sputtering or plasma-assisted chemical conversion characteristics of the surface). The plurality of multilayers provides a selectively resistant coating around high bias regions where ion sputtering occurs near coils. Localize patterning means the placement of the protective coating in one area but not in another area. As a result, regions of the component body 204 that are subjected to more plasma erosion are provided with more protection. In an example, high bias regions near coils may be subjected to higher plasma erosion. Therefore, more multilayer coatings are provided for such regions.

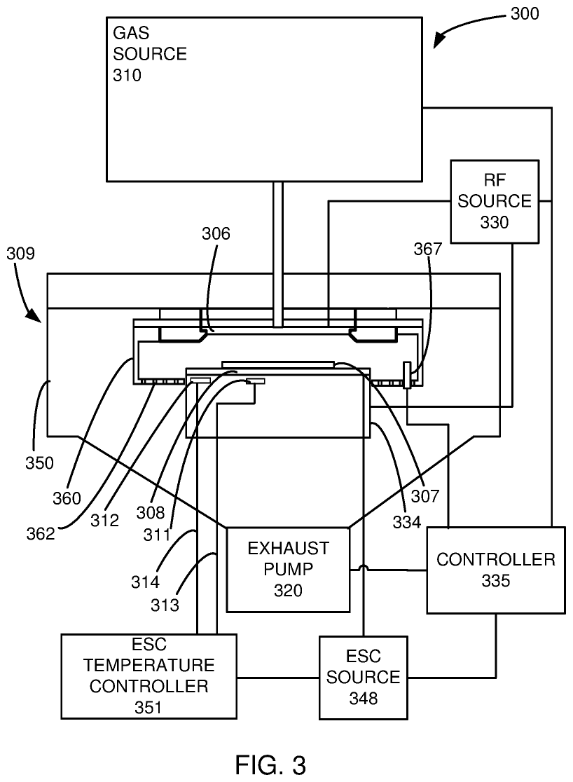

The component is mounted and used in a plasma processing chamber (step 124). FIG. 3 is a schematic view of a plasma processing chamber in which the component may be installed. In one or more embodiments, the plasma processing system 300 comprises a gas distribution plate 306 providing a gas inlet and an electrostatic chuck (ESC) 308, within a plasma processing chamber 309, enclosed by a chamber wall 350. Within the plasma processing chamber 309, a substrate 307 is positioned on top of the ESC 308. The ESC 308 may provide a bias from the ESC source 348. A gas source 310 is connected to the plasma processing chamber 309 through the gas distribution plate 306. An ESC temperature controller 351 is connected to the ESC 308 and provides temperature control of the ESC 308. In this example, a first connection 313 provides power to an inner heater 311 for heating an inner zone of the ESC 308. A second connection 314 provides power to an outer heater 312 for heating an outer zone of the ESC 308. An RF source 330 provides RF power to a lower electrode 334 and an upper electrode. In this embodiment, the upper electrode is the gas distribution plate 306 and is grounded. The lower electrode is the ESC 308. In a preferred embodiment, 13.56 (megahertz (MHz), 2 MHz, 60 MHz, and/or optionally, 27 MHz power sources make up the RF source 330 and the ESC source 348. A controller 335 is controllably connected to the RF source 330, the ESC source 348, an exhaust pump 320, and the gas source 310. A high flow liner 360 is a liner within the plasma processing chamber 309. The high flow liner 360 confines gas from the gas source and has slots 362. The slots 362 maintain a controlled flow of gas to pass from the gas source 310 to the exhaust pump 320. An example of such a plasma processing chamber is the Exelan Flex™ etch system manufactured by Lam Research Corporation of Fremont, Calif. The process chamber can be a CCP (capacitively coupled plasma) reactor or an ICP (inductively coupled plasma) reactor. In this embodiment, the gas distribution plate 306 and/or the high flow liner 360 may be the component body 204 with the coatings. A sensor 367 is positioned to measure part of the high flow liner 360. In some embodiments, the sensor 367 is a trace detector that is able to measure a tracer etched from the high flow liner 360. In other embodiments, the sensor 367 is an optical sensor that optically measures a portion of the high flow liner 360.

The plasma processing chamber 309 is used to plasma process the substrate 307. The plasma processing may be one or more processes of etching, depositing, passivating, or another plasma process. The plasma processing may also be performed in combination with nonplasma processing. Such processes may form byproduct deposits on the exposed process layer 216 and/or may erode material from the exposed process layer 216 and/or may affect the exposed process layer 216 in other ways. FIG. 2C is a cross-sectional view of the component body 204 and alternating process layers 216 and conditioning layers 220 after a plurality of substrates 307 have been processed. Eroded regions 224 of the exposed process layer 216 are created when the plasma etches away or reacts with part of the exposed process layer 216. Deposits 228 may also be formed on top of the exposed process layer 216, during the plasma processing.

After several substrates are processed, the plasma processing chamber 309 is conditioned to improve uniformity and reduce defects. As part of the conditioning, the exposed process layer 216 is removed (step 128), which in turn exposes the next underlying conditioning layer 220. An example of a recipe for selectively removing the exposed process layer such as Y₂O₃ with respect to SiO₂ or ZrO₂ uses a wet clean process to selectively remove the top process layer 216 with respect to the conditioning layer 220. In this embodiment, a wet etch provides infinite selectivity of removing the process layer 216 with respect to the conditioning layer 220. In other words, the process layer 216 can be selectively removed while the conditioning layer 220 remains mostly intact. Inorganic acids such as hydrochloric acid (HCL), nitric acid (HNO₃), or sulfuric acid (H₂SO₄) may be used to selectively remove the process layer 216 with respect to the conditioning layer 220.

FIG. 2D is a cross-sectional view of the component body 204 after the exposed process layer 216 (shown in FIG. 2C) along with the eroded regions 224 (shown in FIG. 2C) and the deposits 228 (shown in FIG. 2C) have been removed, exposing the next underlying conditioning layer 220.

The exposed conditioning layer 220 is then selectively removed with respect to the process layer 216 (step 132). In other words, the exposed conditioning layer 220 is now removed while the process layer 216 remains mostly intact. An example of a recipe to selectively remove the exposed conditioning layer 220 uses a wet etch that selectively etches the conditioning layer 220 with respect to the process layer 216. Hydrofluoric acid is used to selectively etch a conditioning layer 220 of SiO₂ or ZrO₂ without etching a process layer 216 of Y₂O₃. If a conditioning layer 220 of silicon is used with a process layer 216 of Y₂O₃, then potassium hydroxide may be used to selectively etch the conditioning layer 220 with respect to the process layer 216.

FIG. 2E is a cross-sectional view of the component body 204 after the exposed conditioning layer 220 (shown in FIG. 2D) has been removed, exposing the next underlying process layer 216. The fresh unetched and clean exposed process layer 216 is used for processing subsequent wafers allowing for a decrease in defects and an increase in uniformity. The process is then looped back to the step of using the component in the plasma processing chamber (step 124). The steps of using the component in the plasma processing chamber (step 124) to process a plurality of wafers, selectively removing the process layer (step 128), and then selectively removing the conditioning layer (step 132) may be performed for a plurality of cycles. In this embodiment, the process may be repeated for seven cycles.

After all or a predetermined number of the multilayers are removed or consumed, remedial action(s), such as replacement or reconditioning, may be taken with respect to the component 206. For example, the component 206 may be reconditioned by depositing another plurality of multilayers on the component body 204.

This embodiment reduces the frequency of recoating. In this embodiment, the surface 208 of the component body 204 may be cleaned and/or reconditioned with minimal downtime. The reconditioning is provided by two stripping steps with one strip step stripping the process layer 216 and one strip step stripping the conditioning layer 220. The two stripping steps may be wet stripping steps. If thick depositions of contaminants are deposited on the process layer 216, both the process layer 216 and the conditioning layer 220 can be stripped to remove such depositions. This embodiment provides a protective surface for extending the life of a component 206. By encapsulating the conditioning layer 220 with a process layer 216, the conditioning layer 220 is protected from plasma.

In various embodiments, the process layer 216 is of a material that will not contaminate semiconductor processing of the semiconductor devices. In addition, the process layer 216 material is an etch-resistant material that is resistant to the plasma processing. An etch-resistant material is defined as a material where less than 1 nm of the etch-resistant material is etched during the plasma processing.

In various embodiments, each individual process layer 216 has a thickness of between 0.10 nm and 5 microns. In addition, each process layer 216 does not form or generate a contaminant that would interfere with the plasma processing. A contaminant may interfere with the plasma processing by either making the plasma processing less uniform or by contaminating the resulting device so that the resulting device has less desirable properties. In various embodiments, the process layers 216 comprise at least one of inorganic oxide, nitride, inorganic fluoride, or inorganic oxyfluoride.

In various embodiments, the etch-resistant material comprises at least one of a metal oxide, nitride, metal fluoride, or metal oxyfluoride. In various embodiments, the process layer 216 is a layer comprising at least one of a rare earth metal oxide or rare-earth oxyfluoride, or rare-earth fluoride. These can include cerium oxide (CeO₂), yttrium oxide (Y₂O₃), samarium oxide (Sm₂O₃), yttrium oxyfluoride (YOF), yttrium fluoride (YF₃), yttria-alumina composites, (YAG or Y₃Al₅O₁₂), doped composites, crystalline alumina, yttrium-aluminum-perovskite (YAP), yttrium aluminum monoclinic (YAM or Y₄Al₂O₉), aluminum yttria composite, aluminum oxide (Al₂O₃), aluminum oxyfluorides, or erbium oxide (Er₂O₃).

In various embodiments, the process layer 216 may be a mixture of the above materials and provide a transition gradient from one material to another in order to provide transition properties. Such a process layer 216 may be a mixture of two different materials mixed together such as aluminum oxide and yttrium oxide to make a composite film. The process layer 216 may have a transition gradient from aluminum oxide to yttrium oxide by weight percent. The transient gradient may be used to modulate plasma resistance and chemical reactivity of the film.

The conditioning layer 220 is formed from a conditioning material that can be selectively etched with respect to the process layer 216 and, conversely, the process layer 216 can be selectively etched with respect to the conditioning layer 220. In various embodiments, the conditioning layer may be SiO₂, silicon (Si), silicon nitride (SiN), zirconium oxide (ZrO₂), aluminum oxide (Al₂O₃), titanium oxide, tantalum oxide, hafnium oxide, yttrium fluoride (YF₃), yttrium oxyfluoride (YOF), hafnium dioxide (HfO₂), titanium dioxide (TiO₂), tantalum pentoxide (Ta₂O₅), silicon (Si), silicon nitride (Si₃N₄), or a metal nitride, such as titanium nitride (TiN) and tantalum nitride (TaN).

In other embodiments, a conditioning layer 220 may be first deposited on the component body 204 followed by a process layer 216. By depositing a conditioning layer first, a process layer 216 will be on the top of the multilayers.

In other embodiments, the multilayers may be trilayers comprising a process layer, a conditioning layer, and an additional layer. For example, a trilayer of aluminum oxide, zirconium oxide, and yttrium oxide may be used. In some embodiments, there may be at least sixteen multiple layers.

In other embodiments, the component may be a ceramic component or may be made of another mixed composite material. In various embodiments, 3D printing (or additive manufacturing) alongside patterning may be used to deposit either or both the process layer 216 or conditioning layer 220. 3D printing provides precision films without requiring subsequent machining or patterning steps.

In various embodiments, an anneal may be used to further condition the process layers 216 and/or the conditioning layers 220. Thermal treatment, such as sintering or annealing, may help reduce stress from different coefficients of expansion or change the process layers 216 to make the process layers 216 more etch resistant. In other embodiments, the process layers 216 and/or conditioning layers 220 are densified. Densifying reduces the inherent porosity of the film and relieves stress. Densifying improves etch selectivity.

In various embodiments, a detector tracer compound may be provided to detect exposure of the conditioning layer 220 or the process layer 216 or one of the underlayers. The tracer, as will be described below, may be applied as a coating or may be mixed into the materials used to deposit the conditioning layer 220 or process layer 216. A sensor 367, such as an optical sensor, would be used to determine when the process layer 216 or the conditioning layer 220 needs to be removed or when the component needs to be reconditioned. In various embodiment, different process layers 216 may be made from different materials, and/or different conditioning layers 220 may be made from different materials. The optical sensor may comprise a laser system that measures displacement or reflectance.

In one embodiment, each multilayer or group of multilayers is associated with a corresponding detector tracer. Tracers can include chemical compounds, dyes, isotopes, particles, ions, impurities with unique elemental signatures that distinguish a layer from another within the film stack. In such embodiments, the sensor 367 is a tracer detector, that is able to detect a specific detector tracer. In some embodiments, the tracer detector is a spectrometer, profilometer, optical laser, interferometer, X-ray spectrometer, or reflectometer. By detecting and identifying the specific detector tracer, the corresponding multilayer or group of multilayers can be identified and appropriate action(s) can be taken. For example, if the last multilayer or group of multilayers is identified, reconditioning of the component can be initiated. Different tracers may be added to a different component to indicate which component needs conditioning.

In another embodiment, a plasma processing chamber may have different components with different multilayers of process layers 216 and conditioning layers 220. Such a plasma processing chamber may have a first component and a second component. For example, the first component may be an edge ring and the second component may be a liner. In this embodiment, the first component has a first subset of one or more of a first plurality of multiple layers of process layers and conditioning layers forming a coating on a surface of the first component. The second component has a second subset of one or more of a second plurality of multiple layers of process layers and conditioning layers forming a coating on a surface of the second component. In some embodiments, the conditioning layers of the first subset comprise different materials than the conditioning layers of the second subset. In some embodiments, the process layers of the first subset comprise different materials than the process layers of the second subset. Since the conditioning layer over the first component is of a different material than the conditioning layer of the second component, the sensor 367 is able to distinguish whether the conditioning layer from the first component or the second component is exposed. The sensor 367 is able to distinguish different conditioning layers 220 and thus determine which component has a process layer 216 that has been etched through.

In some embodiments, when the sensor 367 indicates that a conditioning layer 220 of the first component is exposed, a first remedial action is taken. In an embodiment, the first remedial action is a conditioning of the first component. In an embodiment, the conditioning of the first component would be to remove the exposed conditioning layer thereby revealing a new unprocessed coating underlayer from multiple layers on a surface of the first component. In another embodiment, the conditioning of the first component is the removal and replacement of the first component with a new first component with a plurality of multilayer components.

In some embodiments, when the sensor 367 indicates that a conditioning layer 220 of the second component is exposed a second remedial action is taken. In an embodiment, the second remedial action is a conditioning of the second component. In an embodiment, the conditioning of the second component would be to remove the exposed conditioning layer thereby revealing a new coating from multiple layers on a surface of the second component. In another embodiment, the conditioning of the second component is the removal and replacement of the second component with a new second component with a plurality of multilayer components.

In an example, a conditioning layer closest to the first component has a first tracer. A conditioning layer closest to the second component has a second tracer that is different than the first tracer. In such an example, when the sensor 367 senses the first tracer, this indicates that the conditioning layer closest to the first component is exposed to plasma, indicating that the first component needs remedial action. In an embodiment, where the conditioning layer closest to the first component is exposed, the remedial action may be removing the conditioning layer and forming multiple alternating layers of conditioning layers and process layers on the surface of the first component. When the sensor 367 senses the second tracer, this indicates that the conditioning layer closest to the second component is exposed to plasma, indicating that the second component needs remedial action. In an embodiment, where the conditioning layer closest to the second component is exposed, the remedial action may be removing the conditioning layer and forming multiple alternating layers of conditioning layers and process layers on the surface of the second component.

In various embodiments, the component may be one or more of a confinement ring, an edge ring, a pinnacle, an electrostatic chuck, an electrode, a ground ring, a chamber liner, and a door liner of a plasma processing chamber. In some embodiments, other semiconductor processing chambers may be used. Some semiconductor processing chambers may be inductively coupled or capacitively coupled or may be a system that uses both inductive coupling and capacitive coupling. Some inductively coupled semiconductor processing chambers have power windows through which inductively coupled power passes. In some embodiments, the semiconductor processing chamber may be used to process the bevel of a semiconductor wafer.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. A plasma processing chamber, comprising:
a first component; and
a first plurality of multilayers disposed over the first component, wherein each multilayer comprises:
a process layer; and
a conditioning layer adjacent to the process layer, wherein the process layer is more etch resistant to a processing plasma than the conditioning layer;
wherein the conditioning layer is configured to be selectively etched with respect to the process layer; and wherein the process layer is configured to be selectively etched with respect to the conditioning layer.

2. The plasma processing chamber, as recited in claim 1, wherein an additional process layer is disposed over the first plurality of multilayers.

3. The plasma processing chamber, as recited in claim 1, wherein the process layer comprises an inorganic oxide, inorganic fluoride, or inorganic oxyfluoride.

4. The plasma processing chamber, as recited in claim 1, wherein the process layer comprises a metal oxide, metal fluoride, or metal oxyfluoride.

5. The plasma processing chamber, as recited in claim 1, wherein the process layer is at least one of cerium oxide (CeO₂), yttrium oxide (Y₂O₃), samarium oxide (Sm₂O₃), yttrium oxyfluoride (YOF), yttrium fluoride (YF₃), aluminum oxide (Al₂O₃), aluminum oxyfluorides, aluminum yttria composite, or erbium oxide (Er₂O₃).

6. The plasma processing chamber, as recited in claim 1, wherein the conditioning layer comprises at least one of ZrO₂, YF₃, YOF, SiO₂, HfO₂, TiO₂, TiN, Ta₂O₅, TaN, Si, Si₃N₄, Al₂O₃, or a m.

7. The plasma processing chamber, as recited in claim 1, wherein each process layer has a thickness between 0.1 nm to 5 microns, inclusive.

8. The plasma processing chamber, as recited in claim 1, wherein each conditioning layer has a thickness between 0.1 nm to 5 microns, inclusive.

9. The plasma processing chamber, as recited in claim 1, further comprising a tracer detector configured to detect when the conditioning layer or the process layer is exposed.

10. The plasma processing chamber, as recited in claim 9, wherein at least one of a process layer and a conditioning layer comprises a tracer compound, wherein the tracer compound is configured to be detected by the tracer detector when the conditioning layer or process layer is exposed.

11. The plasma processing chamber, as recited in claim 10, wherein the tracer compound comprises at least one of chemical compounds, dyes, isotopes, particles, ions, and impurities with unique elemental signatures.

12. The plasma processing chamber, as recited in claim 1, wherein erosion of the first plurality of multilayers triggers one or more remedial actions with respect to the first plurality of multilayers.

13. The plasma processing chamber, as recited in claim 12, wherein the one or more remedial actions comprises at least one of reconditioning and replacing the first plurality of multilayers.

14. The plasma processing chamber, as recited in claim 13, wherein the reconditioning comprises depositing an additional plurality of multilayers over the first plurality of multilayers.

15. The plasma processing chamber, as recited in claim 14, wherein the reconditioning further comprises stripping one or more of the first plurality of multilayers before depositing the additional plurality of multilayers.

16. The plasma processing chamber, as recited in claim 12, wherein the one or more remedial actions comprise removing a process layer and removing a conditioning layer.

17. The plasma processing chamber, as recited in claim 1, wherein a first subset of one or more of the first plurality of multilayers is made up of a first material and a second subset of one or more of the first plurality of multilayers is made up of a second material, and wherein the first material and the second material enable corresponding remedial actions to be taken with respect to the first subset and the second subset.

18. The plasma processing chamber, as recited in claim 1, further comprising a second component and a second plurality of multilayers disposed over the second component, wherein the first plurality of multilayers and the second plurality of multilayers are made up of different materials.

19. The plasma processing chamber, as recited in claim 18, further comprising sensing material from either the first plurality of multilayers or materials from the second plurality of multilayers, wherein the sensing the materials enable corresponding remedial actions to be taken with respect to the first component and the second component.

20. The plasma processing chamber, as recited in claim 19, wherein the remedial actions include at least one of reconditioning and replacement of at least one of the first component and the second component.

21. The plasma processing chamber, as recited in claim 1, wherein the first component includes at least one of a confinement ring, an edge ring, a pinnacle, an electrostatic chuck, an electrode, a ground ring, a chamber liner, and a door liner.

22. The plasma processing chamber, as recited in claim 1, wherein the first component includes at least one surface; wherein the first plurality of multilayers is selectively patterned on at least one or more regions on the at least one surface; and wherein the at least one or more regions are relatively more subjected to plasma erosion during plasma processing from sputtering or plasma-assisted chemical conversion characteristics than other regions of the at least one surface that are not patterned with the first plurality of multilayers.

23. The plasma processing chamber, as recited in claim 22, wherein the first plurality of multilayers provides a selectively resistant coating around high bias regions where ion sputtering occurs near coils.

24. A component for use in a plasma processing chamber, comprising:
a component body; and
a first plurality of multilayers disposed over the component body, wherein each multilayer comprises:
a process layer; and
a conditioning layer adjacent to the process layer, wherein the process layer is more etch resistant to a processing plasma than the conditioning layer;
wherein the conditioning layer is configured to be selectively etched with respect to the process layer; and wherein the process layer is configured to be selectively etched with respect to the conditioning layer.

25. The component, as recited in claim 24, wherein an additional process layer is disposed over the first plurality of multilayers.

26. The component, as recited in claim 24, wherein the process layer comprises an inorganic oxide, inorganic fluoride, or inorganic oxyfluoride.

27. The component, as recited in claim 24, wherein the process layer comprises a metal oxide, metal fluoride, or metal oxyfluoride.

28. The component, as recited in claim 24, wherein the process layer is at least one of cerium oxide (CeO₂), yttrium oxide (Y₂O₃), samarium oxide (Sm₂O₃), yttrium oxyfluoride (YOF), yttrium fluoride (YF₃), aluminum oxide (Al₂O₃), aluminum oxyfluorides, aluminum yttria composite, or erbium oxide (Er₂O₃).

29. The component, as recited in claim 24, wherein the conditioning layer comprises at least one of ZrO₂, YF₃, YOF, SiO₂, HfO₂, TiO₂, TiN, Ta₂O₅, TaN, Si, Si₃N₄, Al₂O₃, or a metal nitride.

30. A method of using a first component, wherein the first component has a first plurality of multilayers disposed over the first component, wherein each multilayer comprises a process layer made of an etch-resistant material, wherein the etch-resistant material does not form a contaminant during plasma processing and a conditioning layer adjacent to the process layer, wherein the conditioning layer is configured to be selectively etched with respect to the process layer and wherein the process layer is configured to be selectively etched with respect to the conditioning layer, the method comprising a plurality of cycles, wherein each cycle comprises:
using the first component in a plasma processing chamber to process a plurality of wafers in the plasma processing chamber;
selectively removing an exposed process layer with respect to conditioning layer; and
selectively removing an exposed conditioning layer with respect to a process layer.

31. The method, as recited in claim 30, wherein the using the first component in the plasma processing chamber to process the plurality of wafers in the plasma processing chamber either forms a deposition on the exposed process layer or erodes the exposed process layer or both forms a deposition on the exposed process layer and erodes the exposed process layer.

32. The method as recited in claim 30, wherein the selectively removing the exposed process layer comprises, providing a wet etch that selectively etches the process layer with respect to the conditioning layer.

33. The method as recited in claim 32, wherein the selectively removing the exposed conditioning layer comprises, providing a wet etch that selectively etches the conditioning layer with respect to the process layer.

34. The method, as recited in claim 32, wherein the etch-resistant material comprises an inorganic oxide, inorganic fluoride, or inorganic oxyfluoride.

35. The method, as recited in claim 32, wherein the etch-resistant material comprises at least one of cerium oxide (CeO₂), yttrium oxide (Y₂O₃), samarium oxide (Sm₂O₃), yttrium oxyfluoride (YOF), yttrium fluoride (YF₃), aluminum oxide (Al₂O₃), aluminum oxyfluorides, aluminum yttria composite, or erbium oxide (Er₂O₃).

36. The method, as recited in claim 30, wherein the conditioning layer comprises at least one of ZrO₂, YF₃, YOF, SiO₂, HfO₂, TiO₂, TiN, Ta₂O₅, TaN, Si, Si₃N₄, Al₂O₃, or a metal nitride.

37. The method, as recited in claim 30, further comprising providing a plurality of cycles, wherein each cycle comprises:
forming a conditioning layer over the first component; and
forming a process layer over the conditioning layer.

38. The method, as recited in claim 37, wherein the forming the conditioning layer comprises patterning the conditioning layer and wherein the forming the process layer comprises patterning the process layer.

39. The method, as recited in claim 30, further comprising using a secondary component, wherein the secondary component has a plurality of secondary multilayers on the secondary component, wherein each secondary multilayer comprises a secondary process layer of a secondary etch-resistant material, wherein the secondary etch-resistant material does not form a contaminant during plasma processing and a secondary conditioning layer that is able to be selectively etched with respect to the secondary process layer and wherein the secondary process layer may be selectively etched with respect to the secondary conditioning layer, the method comprising distinguishing if contaminants come from the conditioning layer or from the secondary conditioning layer and distinguishing whether the conditioning layer or secondary conditioning layer is exposed.
